(19) United States
(12) Patent Application Publication
(10) Pub. No.: US 2019/0279945 A1
(43) Pub. Date: Sep. 12, 2019

(54) ELECTRONIC CIRCUIT WITH GUARD FEATURES FOR RELIABILITY IN HUMID ENVIRONMENTS

(71) Applicant: Texas Instruments Incorporated, Dallas, TX (US)

(72) Inventor: JIYUAN LUAN, FREMONT, CA (US)

(21) Appl. No.: 15/913,621

(22) Filed: Mar. 6, 2018

(51) Int. Cl. H01L 23/00; H05K 1/18; H05K 1/11; H05K 1/09; C23F 13/20

(52) U.S. Cl. CPC H01L 23/564; H05K 1/181; H05K 1/115; C23F 2213/30; C23F 13/20; H05K 2201/10166; H05K 1/09

(57) ABSTRACT

An electronic circuit includes a substrate having functional circuitry configured to realize and carry out at least one functionality. At least one guard feature is positioned between a first feature including a metal that is coupled to a node in the electronic circuit configured for being biased at a first voltage to operate as an anode and a second feature including the metal which is coupled to a node in the circuitry circuit configured for being biased at a second voltage<the first voltage to operate as a cathode to enable dendritic growth of the metal on the cathode. The functional circuitry includes a plurality of interconnected transistors, the anode, and the cathode which are configured for implementing the functionality, wherein the guard feature does not contribute to the functionality of the circuit.

### FIELD

This Disclosure relates to protection of electronic circuits from the effects of moisture during operation, such as metal corrosion.

### BACKGROUND

Significant moisture levels in the air reflected in the humidity resulting in metal corrosion has long been a problem for electronic circuits, both at the board level (for printed circuit boards (PCBs)) and the integrated circuit (IC) level. The relative humidity is the ratio of the actual moisture in the air to the highest amount of moisture that can be held in the air, which is a function of the air temperature. The warmer the air temperature is, the more moisture the air can hold, which is reflected in a higher dew point that is defined as the air temperature having (or that would have) a 100% relative humidity.

Condensation of water vapor from the air happens when the moisture in the air touches a surface with a temperature at or below the dew point. For example, condensation on exposed metal lines or bond pads of an electronic circuit may lead to bond pad and/or metal interconnect line corrosion which is an electrochemical process. Condensation is generally regarded as a chief contributor to corrosion, where due to self-ionization, water can function as an electrolyte especially at elevated temperatures and/or in the presence of impurities that allows intimate access of concentrated contaminating species (some of which become strong acids in the presence of water) and transportation of corrosion products. Corrosion occurs in the presence of a direct current (DC) potential difference between metal features (e.g., metal lines, vias, or bond pads) sufficient to oxidize the metal of one metal feature to form a metal cation (e.g., Cu metal) (Cu⁰) which oxidizes to become Cu⁺²+2e⁻) on the (+) biased anode, and the metal cations (e.g., Cu⁺²) generated at the anode can be sufficiently mobile to migrate to another metal feature that is (−) biased that acts as an cathode where the metal cations can be reduced to return to its atomic metal form (e.g., Cu⁺²+2e⁻ to become deposited Cu⁰); generally in the form of crystals called ‘dendrites’. The deposition of dendrites can result in extending out from the metal feature acting as the cathode to neighboring node(s), at distances up to about 100 mm or more, which can create shorts on the electronic circuit.

Corrosion of metal features can be mitigated in several known ways. The materials used for the metal features can be selected more wisely, such as based on available corrosion data. The electrically conductive materials can be protected by the use of protective coatings, device enclosures, or in some limited applications by the relocation of the equipment having the electronic circuit to more protected environments. A fixed DC bias can be used such as in telecommunications and wireless network applications in which the positive side of the DC bias is grounded. However, this positive ground arrangement is incompatible with the prevailing IC bias scheme and applications.

A passivation layer comprising silicon nitride or silicon oxynitride may provide better environmental performance as compared to conventional silicon oxide passivation. However, the passivation layer needs to be exposed over the metal features such as bond pad areas to allow electrical contact thereto, typically by a bondwire, which renders the exposed bond pad areas susceptible to corrosion.

### SUMMARY

This Summary is provided to introduce a brief selection of disclosed concepts in a simplified form that are further described below in the Detailed Description including the drawings provided. This Summary is not intended to limit the claimed subject matter's scope.

This Disclosure recognizes known techniques for mitigating corrosion of metal features on electronic circuits are conventionally passive (non-electrically biased) techniques, such as special metal compositions and protective coatings. Such known techniques for mitigating metal corrosion has only marginal effectiveness because under normal operating conditions, electronic circuits are usually DC biased, therefore in the presence of moisture these circuits can form electrochemical cells which drive non-spontaneous redox reactions through the application of electrical energy, resulting in corrosion with metal species normally considered inert under unbiased conditions. As described above, the known positive ground configuration used in today's telecommunications and wireless industry does not work on the circuit level because it is incompatible with today's electronic circuit bias schemes, and does not provide corrosion protection if the grounded positive conductor is also a metal feature prone to corrosion itself. Furthermore, the thermal stress caused by an electronic circuit operation under different loading and power on/off conditions can induce delamination between the protective coating and substrate, creating a space which can become vulnerable to condensation-induced moisture ingression.

As a result, electronic circuits currently experience humidity-induced metal corrosion which can cause circuit reliability failures. For example, high voltage temperature-humidity biased test (THBT) and highly accelerated stress test (HAST) burn-in boards have electronic circuit units routinely fail during reliability tests (under humidity and bias conditions), causing non-genuine electrical over-stress (EOS) type of failures. Disclosed corrosion-protected electronic circuits and electronic circuit corrosion protection methods instead use additional dedicated conductive ‘guard’ features (e.g., guard traces or guard vias) added to the electronic circuit that are positioned between respective metal feature pairs on the electronic circuit deemed susceptible to corrosion that upon DC biasing in the presence of moisture can act as an anode and cathode pair to initiate corrosion, where oxidation occurs at the anode generating mobile cations.

During operation of the electronic circuit, an AC bias is provided between the cathode and the guard feature which generates an AC electromagnetic field in the migration path of the cations generated at the anode to help avoid their migration from reaching a concentrated spot in the cathode-side of the circuit. The disclosed AC electromagnetic field applied in the migration path thus significantly slows down the directional growth of the electrically conductive dendrite on the cathode.

By introducing a disclosed AC bias which generates an interference electromagnetic field, the migration of the mobile cations is guided by the combined electromagnetic field (from the superpositioning of AC field from the AC bias with the static field from the DC bias), which is thus a time and space varying combined electromagnetic field. Instead of mobile cations conventionally accumulating and being reduced at a very concentrated spot (growth point of the dendrite), the mobile cations are instead accumulated and are reduced over a larger area, effectively preventing them from forming dendrites on the cathode. This disclosed arrangement provides more reliable electronic circuits, particularly when operating in humid environments. The guard features do not contribute to a functionality provided by the electronic circuit, and thus are provided for only cation dispersion and ion immobilization to reduce or eliminate humidity-induced electronic circuit failures.

Disclosed aspects include a method of protecting an electronic circuit from corrosion including providing a guard feature positioned between a first metal feature in the electronic circuit comprising a metal that is coupled to a first node in the electronic circuit which is biased at a higher voltage side of a DC bias voltage to operate as an anode which generates mobile cations. A second metal feature in the electronic circuit is coupled to a second node that is biased at a lower voltage side of the DC bias voltage to operate as a cathode.

The electronic circuit includes functional circuitry configured for implementing at least one functionality comprising a plurality of interconnected transistors, the anode, and the cathode, wherein the guard feature does not contribute to the circuit's functionality. An AC signal is applied between the guard feature and the cathode, wherein the AC signal generates an electromagnetic field in a migration path of the mobile cations to interfere with their migration from reaching to a localized area of the cathode. Disclosed metal cation interference can disrupt the formation of reduced metal atoms at any localized area, and can also slow down or even prevent dendritic growth from occurring at metal features that can otherwise function as cathodes.

### BRIEF DESCRIPTION OF THE DRAWINGS

Reference will now be made to the accompanying drawings, which are not necessarily drawn to scale, wherein:

FIG. 1 depicts a metal corrosion mechanism on an electronic circuit comprising a substrate including a first metal feature shown as an anode and a second metal feature shown as a cathode resulting from being DC biased relative to one another, including oxidation at the anode which is (+) biased to generate Cu²⁺ cations, Cu²⁺ migration, and then Cu²⁺ reduction causing accumulation at the cathode which is biased to form dendrites thereon.

FIG. 2 depicts a simplified example circuit implementation including an added guard trace positioned between the anode and the cathode shown in FIG. 1, where an AC voltage source provides an AC signal that is applied between the guard trace and the cathode to provide protection against dendritic growth at the cathode by providing an electromagnetic field that interferes with the Cu²⁺ migration to the cathode, according to an example aspect.

FIG. 3A depicts a perspective view of a simplified portion of an example electronic circuit showing corrosion vulnerable signal vias with guard vias between vulnerable signal vias comprising a first vulnerable signal via and a second vulnerable signal via, according to an example aspect.

FIG. 3B depicts a perspective view of a simplified portion of an example electronic circuit showing corrosion vulnerable traces with guard traces between vulnerable traces comprising a first vulnerable signal trace and a second vulnerable signal trace, according to an example aspect.

FIG. 4 shows a cross sectional view of an example corrosion protected IC showing a complementary metal-oxide-semiconductor (CMOS) inverter include an NMOS and a PMOS transistor including a first and a second guard trace between the sensitive traces, according to an example aspect.

FIG. 5 shows experimental results of dendrite fusing time (y-axis) in aqueous solution between copper features spaced apart about 60 mm under a DC bias provided by an applied DC current (x-axis) showing theoretically calculated, measured results from bench testing, and results from adding a disclosed guard feature and the applying an AC signal between the guard feature and the copper feature acting as the cathode that is shown preventing dendritic growth across the full current range.

### DETAILED DESCRIPTION

Example aspects in this disclosure are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

Also, the terms “coupled to” or “couples with” (and the like) as used herein without further qualification are intended to describe either an indirect or direct electrical connection. Thus, if a first device “couples” to a second device, that connection can be through a direct electrical connection where there are only parasitics in the pathway, or through an indirect electrical connection via intervening items including other devices and connections. For indirect coupling, the intervening item generally does not modify the information of a signal but may adjust its current level, voltage level, and/or power level.

This Disclosure provides electronic circuit corrosion protection methods and electronic circuit architectures that add a guard feature between a pair of spaced apart metal features that otherwise when DC biased during circuit operation can function as an electrolytic cell (anode and cathode), resulting in metal oxidation at the anode generating metal cations and reduction of the metal cations that reach the cathode resulting in dendritic growth on the cathode. The metal features can be metal lines, bond pads, bonding wires, or through-hole or buried vias on the electronic circuit.

During circuit operation, one of these metal features when DC based positively (+) can become an anode relative to the other metal feature that during circuit operation when DC based negatively (−) relative to the other metal feature can become a cathode. These metal features are generally spaced ≤100 mm from one another, such as a spacing of ≤10 mm. To prevent dendritic growth on the cathode, an AC signal is applied between the cathode and the guard feature so that during circuit operation the reliability is improved particularly in high humidity conditions due to the elimination or at least the reduction of dendritic growth at the cathode, and thus the elimination or at least the lessening of metal corrosion.

The electronic circuit has circuitry configured to realize and carry out a desired functionality, such as that of a digital IC (e.g., digital signal processor) or analog IC (e.g., amplifier or power converter), and in one embodiment a BiCMOS (MOS and Bipolar) IC. The functionality provided on a disclosed electronic circuit can vary, for example ranging from a simple device to a complex device. The specific functionality contained within functional circuitry is not of importance to disclosed electronic circuits. As described above, disclosed guard features do not contribute to the functionality provided by the electronic circuit and are provided for only ion dispersion and ion immobilization to reduce or eliminate humidity-induced electronic circuit failures.

The AC signal can be a sinusoid, triangular, or square wave waveform. Because of the AC electromagnetic field generated by the AC signal, mobile cations (e.g., Cu²⁺) that are generated at the anode are dispersed into a larger area/volume instead of conventional migration along the highest electric field area into a concentrated, localized area. This cation dispersion minimizes the possibility for the cations generated at the anodes to align with the electric field lines, which disrupts the necessary migration process needed to form dendrites at the cathodes.

An AC electromagnetic field, also known in physics as an electromotive force (EMF) or EM field, is a physical field produced by moving electrically charged objects that affects the behavior of charged objects in the vicinity of the field. The EM field strength is determined by the voltage, the higher the voltage, the stronger the EM field. The EM field can be viewed as the combination of an AC electric field and an AC magnetic field. An AC field by definition continually changes polarity from positive to negative over time. The AC electric field introduced can also electrolyze condensed water molecules on the surface of the electronic circuit, generating hydroxide (OH⁻) ions in the region, which can combine with cations such as Cu²⁺ in the case of copper (Cu) features to neutralize its electrical charge, immobilizing the cations. For example, once Cu²⁺ reacts with the generated OH⁻ ions, Cu compounds can precipitate from the solution, by forming non-electrically conductive or weakly electrically conductive copper oxide (CuO or Cu₂O) byproducts. Similar chemistry holds for aluminum features.

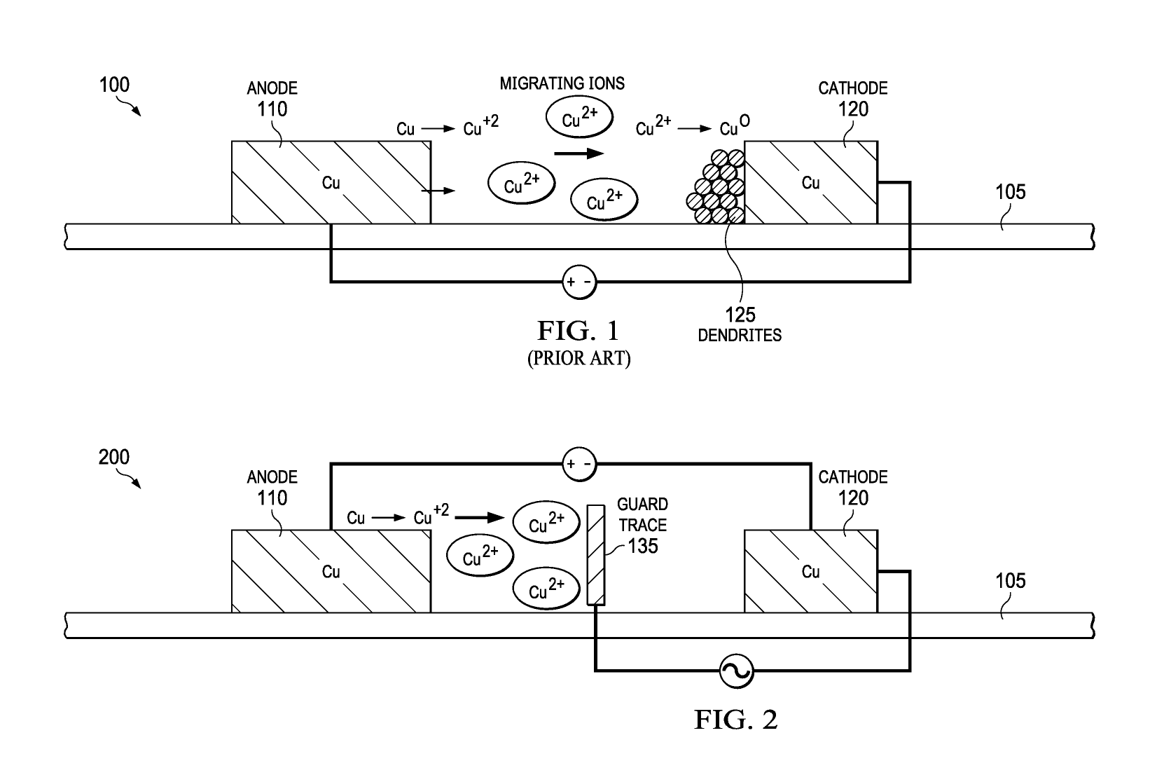

FIG. 1 depicts a metal corrosion mechanism on an electronic circuit 100 comprising a substrate 105 including a first metal feature shown as an anode 110 and a second metal feature shown as a cathode 120 resulting from being DC biased relative to one another. The electronic circuit 100 can be an IC die, or a PCB. Both the anode 110 and the cathode 120 are shown as comprising Cu, with the corrosion mechanism comprising oxidation at the anode 110 which is (+) biased to generate Cu cations (Cu⁺²), Cu⁺² migration (typically in water condensed on the circuit surface acting as an electrolyte) under influence of an electric field, and then Cu⁺² reduction at the cathode 120 which is (−) biased causing entrapment at the cathode 120. Cu dendrites 125 formed at the cathode 120 reduces the effective distance between the anode 110 and the cathode 120 that eventually can result in a short circuit developing between the anode 110 and the cathode 120, or between the cathode 120 and another node on the electronic circuit.

FIG. 2 depicts a simplified example circuit implementation showing an electronic circuit 200 that modifies the electronic circuit 100 shown in FIG. 1 to add a guard feature shown as a guard trace 135 positioned between the anode 110 and the cathode 120, according to an example aspect. One can determine placement of disclosed guard features using simulation of the electronic circuit, or a failure analysis of the electronic circuit. An AC signal from an AC signal source is shown applied between the guard trace 135 and the cathode 120 to provide protection against dendritic growth at the cathode 120 by providing an AC electromagnetic field which interferes with the Cu⁺² migration from around the anode 110 from reaching a localized area at the cathode 120. There are no dendrites (shown in FIG. 1) shown on the cathode 120 in FIG. 2.

The waveform, amplitude and frequency of the AC signal utilized can vary depending on the application and the placement of the guard features. In general, the amplitude of the AC signal is equal or less than the DC bias voltage between the two corrosion susceptible features, but high enough to create an AC electric field disrupting the mobile cation migration from the anode to cathode. The signal frequency is generally a low frequency to reduce AC power dissipation, but high enough to perturb the directional migration of the mobile ions, such as tens of Hz to hundreds of Hz, for example, 10 Hz to 500 Hz.

The placement of the guard features which function as perturbation electrodes is to establish an AC field in the migration path of the mobile ion. The most effective perturbation electrode placement is on the transverse side of the anode to cathode direction, but guard features can be also placed near this path on different layers or on sides of the conductor traces.

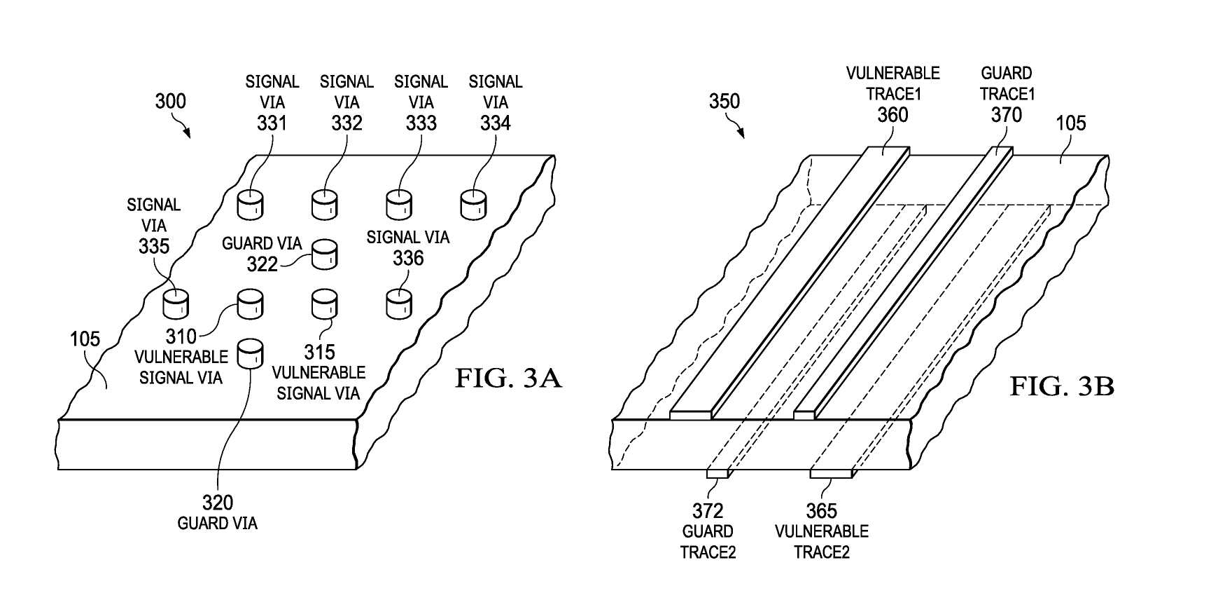

FIG. 3A depicts a perspective view of a simplified portion of an example electronic circuit 300 showing corrosion vulnerable signal vias 310 (say DC biased to be an anode), signal vias 315 (say DC biased to be a cathode with respect to the anode), with guard vias 320, 322 positioned between the vulnerable signal vias 310, 315, according to an example aspect. During circuit operation, as described above the guard vias 320, 322 are connected to bond pads on an IC or traces on a PCB and are used for applying an AC signal between at least one of the guard vias 320, 322 and the vulnerable signal via 315 that is biased as a cathode to generate an electromagnetic field between the vulnerable signal vias 310 and 315 that inhibits and/or prevents the migration of mobile cations from the vulnerable signal via 310 acting as an anode to the vulnerable signal via 315 acting as a cathode. Other signal vias shown as signal vias 331, 332, 333, 334, 335 and 336 that were not determined to be corrosion vulnerable circuit nodes do not include a disclosed guard via positioned nearby.

FIG. 3B depicts a perspective view of a simplified portion of an example electronic circuit 350 showing a first corrosion vulnerable trace shown as vulnerable trace 1 360 and a second corrosion vulnerable trace shown as vulnerable trace 2 365, with a guard trace 1 370 and a guard trace 2 372 between the vulnerable traces 360, 365, according to an example aspect. In one example vulnerable trace 1 360 may be DC biased to be a cathode, and vulnerable trace 2 365 may be DC biased to be an anode. During circuit operation, the guard traces 370, 372 are connected to bond pads on an IC or traces on a PCB used for applying an AC signal between the guard traces 370, 372 and the vulnerable trace (vulnerable trace 1 360 in this example) acting as a cathode.

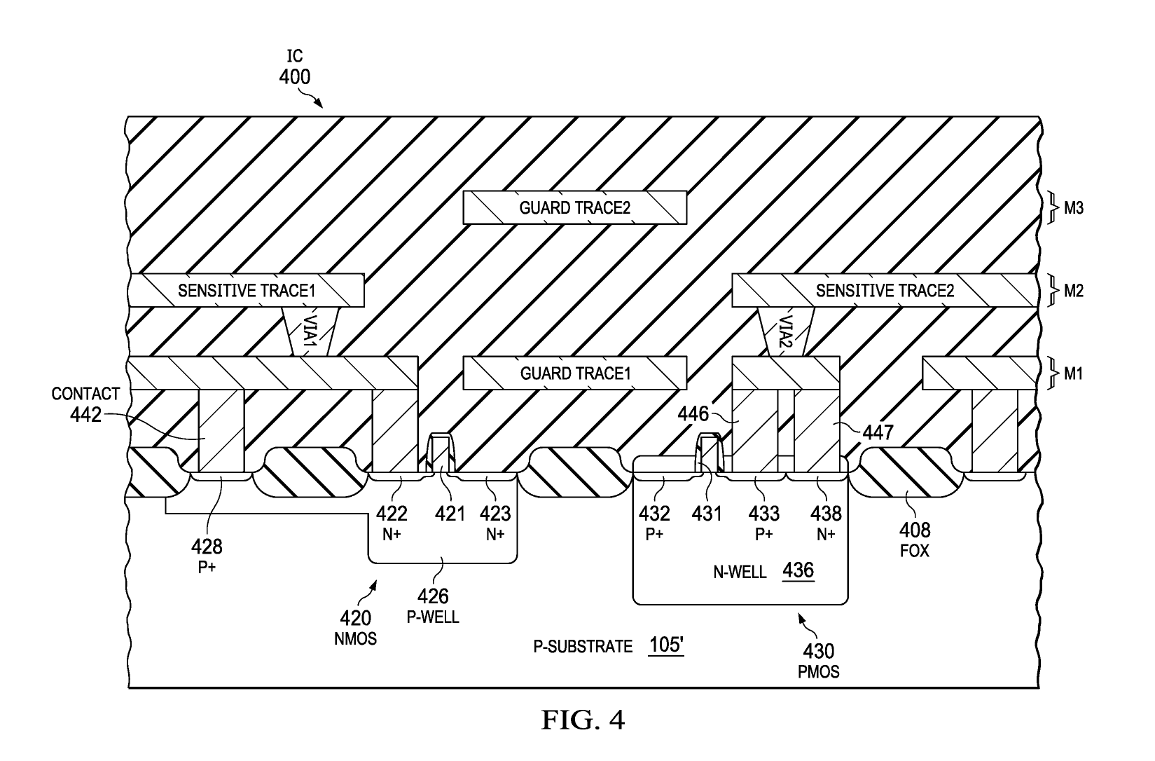

FIG. 4 shows a cross sectional view of an example corrosion protected IC 400 formed on a substrate 105′ shown as a p− substrate showing a CMOS inverter include an NMOS transistor 420 and a PMOS transistor 430 separated by field oxide (FOX) 408 shown for example as local oxidation of silicon (LOCOS) including a guard trace 1 and guard trace 2 between the sensitive trace 1 (that may be DC biased to be an anode) and sensitive trace 2 (that may be DC biased to be a cathode), according to an example aspect. Guard trace 1 is shown formed in metal 1 (M1), and guard trace 2 is shown formed in M3. FIG. 4 shows the guard traces are not always on the same metal level as the anode trace and cathode trace, so that disclosed guard features can also be placed around sensitive features (nodes), but not necessary on the same metal layer.

The NMOS transistor 420 includes a gate 421, with an n+ source 422, and n+ drain 423 in a p−well 426 that has a p+ pwell contact 428. The PMOS transistor 430 includes a gate 431, with a p+ drain 432 and p+ source 433 both in an n−well 436. There is also an n+ nwell contact 438. Although not shown in FIG. 4 there is a needed connection to implement a CMOS inverter between the p+ drain 432 of the PMOS transistor and the n+ drain 423 of the NMOS transistor 420. Sensitive trace 1 is shown formed in M2 and is shown coupled to the p+ pwell contact 428 by vial to M1 and a contact 442 from M1 to the pwell contact 428. Similarly, sensitive trace 2 is shown formed in M2 and is shown coupled to the p+ source 433 and nwell contact 438 by via2 to M1, and contacts 446, 447 from M1 shown coupled to the p+ source 433 and n+ nwell contact 438, respectively.

### EXAMPLES

Disclosed aspects are further illustrated by the following specific Examples, which should not be construed as limiting the scope or content of this Disclosure in any way.

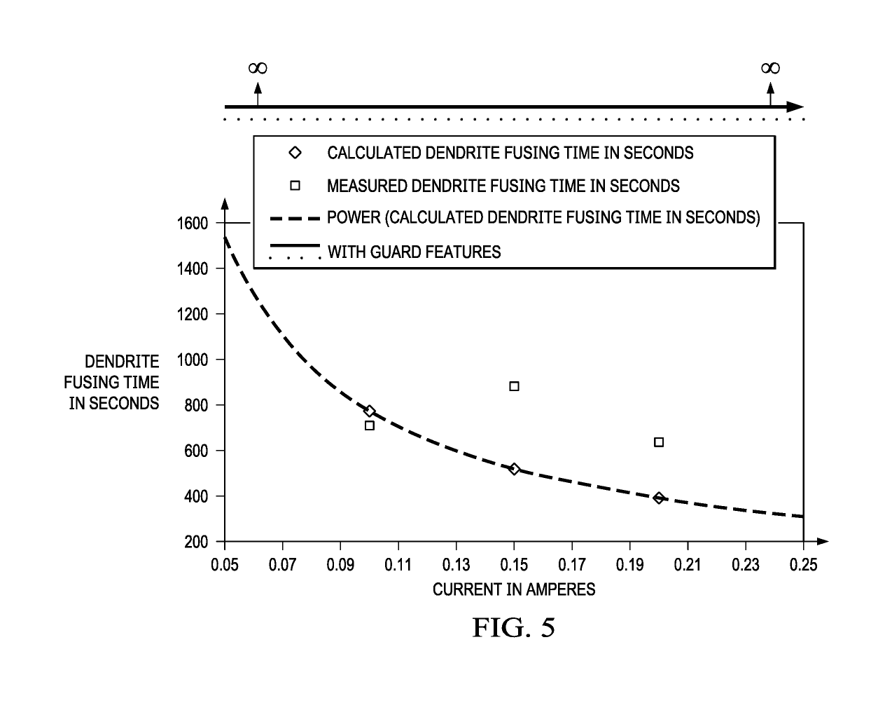

FIG. 5 shows room-temperature experimental results of dendrite fusing time (y-axis) in aqueous solution between copper features spaced apart about 60 mm under a DC bias provided by DC current (x-axis) vs. current showing theoretically calculated, measured results from bench testing, and results from adding a disclosed guard trace between the features and applying an AC signal at 100 Hz and a 10V peak-to-peak voltage between the guard feature and the copper feature biased to act as the cathode. The DC bias was provided by the forcing of the DC current that was 0.05 A to 0.25 A. The AC signal applied between the guard feature and the copper feature acting as the cathode prevented dendritic growth at the cathode, and these results are thus shown in FIG. 5 as t=an infinite fusing time across the full current range shown.

Those skilled in the art to which this Disclosure relates will appreciate that many other variations are possible within the scope of the claimed invention, and further additions, deletions, substitutions and modifications may be made to the described aspects without departing from the scope of this Disclosure.

1. A method of protecting an electronic circuit from corrosion, comprising:
providing a guard feature positioned between a first metal feature in the electronic circuit comprising a metal that is coupled to a first node in the electronic circuit which is biased at a higher voltage side of a DC bias voltage to operate as an anode which generates mobile cations and a second metal feature in the electronic circuit coupled to a second node in the electronic circuit that is biased at a lower voltage side of the DC bias voltage to operate as a cathode, wherein the electronic circuit includes functional circuitry configured for implementing at least one functionality comprising a plurality of interconnected transistors, the anode, and the cathode, wherein the guard feature does not contribute to the functionality, and
applying an alternating current (AC) signal between the guard feature and the cathode, wherein the AC signal generates an electromagnetic field in a migration path of the mobile cations to prevent their migration from reaching the cathode.

2. The method of claim 1, wherein an amplitude of the AC signal is less than or equal to a level of the DC bias voltage.

3. The method of claim 1, wherein the AC signal comprises a sinusoid, triangular, or square wave waveform.

4. The method of claim 1, wherein a frequency of the AC signal is in a range from 10 Hz to 500 Hz.

5. The method of claim 1, wherein the guard feature is a trace comprising an electrically conductive material or a via filled with the electrically conductive material.

6. The method of claim 1, wherein the electrically conductive material comprises a copper or aluminum.

7. The method of claim 1, further comprising determining placement of the guard feature using a simulation of the electronic circuit or a failure analysis of the electronic circuit.

8. The method of claim 1, wherein the electronic circuit comprises an integrated circuit (IC) including a semiconductor substrate.

9. The method of claim 1, wherein the electronic circuit comprises a printed circuit board (PCB).

10. The method of claim 1, wherein the anode and the cathode are spaced apart by ≤100 mm.

11. The method of claim 1, wherein the electromagnetic field from the AC signal is sufficient to electrolyze condensed water on a surface of the electronic circuit to form OH⁻ and H⁺, wherein the OH⁻ combines with the mobile cations to form a compound that precipitates on the electronic circuit.

12. An electronic circuit, comprising:
a substrate having functional circuitry configured to realize and carry out at least one functionality, and
at least one guard feature positioned between a first feature comprising a metal that is coupled to a first node in the electronic circuit configured for being biased at a first voltage to operate as an anode and a second feature comprising the metal which is coupled to a second node in the electronic circuit configured for being biased at a second voltage<the first voltage to operate as a cathode to enable dendritic growth of the metal on the cathode, wherein the functional circuitry comprises a plurality of interconnected transistors, the anode, and the cathode configured for implementing the functionality;
wherein the guard feature does not contribute to the functionality.

13. The electronic circuit of claim 12, wherein the guard feature is a trace comprising an electrically conductive material or a via filled with the electrically conductive material.

14. The electronic circuit of claim 12, wherein the electronic circuit comprises an integrated circuit (IC) including a semiconductor substrate.

15. The electronic circuit of claim 12, wherein the electronic circuit comprises a printed circuit board (PCB).

16. The electronic circuit of claim 12, wherein the metal comprises copper or aluminum.

17. The electronic circuit of claim 12, wherein the guard feature is on a different metal level compared to a metal level for the anode or a metal level for the cathode.

18. The electronic circuit of claim 12, wherein the anode and the cathode are spaced apart by ≤100 mm.

19. The electronic circuit of claim 12, wherein the anode and the cathode are spaced apart by ≤20 mm.

20. The electronic circuit of claim 12, wherein the guard feature comprises the metal.

21. The electronic circuit of claim 12, wherein the electronic circuit is adapted to receive an alternating current (AC) signal applied between the guard feature and the cathode to generate an electromagnetic field in a migration path of mobile cations to prevent their migration from the anode to the cathode.

22. The electronic circuit of claim 12, wherein the electronic circuit is adapted to receive an alternating current (AC) signal applied between the guard feature and the cathode to generate an electromagnetic field to inhibit migration of mobile cations from the anode to the cathode.

23. The electronic circuit of claim 12, further including circuitry for generating an alternating current (AC) signal and coupling it between the guard feature and the cathode to generate an electromagnetic field in a migration path of mobile cations to prevent their migration from the anode to the cathode.

24. The electronic circuit of claim 12, further including circuitry for generating an alternating current (AC) signal and coupling it between the guard feature and the cathode for generating an electromagnetic field to inhibit migration of mobile cations from the anode to the cathode.
